(19) United States
(12) Patent Application Publication
(10) Pub. No.: US 2024/0387217 A1
(43) Pub. Date: Nov. 21, 2024

(54) EQUIPMENT FRONT END MODULE

(71) Applicant: ASM IP Holding B.V., Almere (NL)

(72) Inventor: Hsuan Te Lin, Kawasaki-shi (JP)

(21) Appl. No.: 18/666,277

(22) Filed: May 16, 2024

Related U.S. Application Data
(60) Provisional application No. 63/467,533, filed on May 18, 2023.

(51) Int. Cl. H01L 21/673; H01L 21/677

(52) U.S. Cl. CPC H01L 21/67393; H01L 21/67766; H01L 21/67778

(57) ABSTRACT

A substrate processing apparatus may comprise: an equipment front end module comprising a housing bounded by front and back walls, first and second side walls between the front back walls, a top wall, and a bottom wall; a load port connected to the front wall and configured to receive a front opening unified pod (FOUP); a load lock chamber connected to the back wall and configured to load or unload a substrate; a front-end robot disposed in the housing and configured to transfer the substrate between the FOUP and the load lock chamber; a fan filter unit (FFU) connected to the top wall and configured to provide filtered air to the housing; and an air intake port provided above the FFU, and comprising an air inlet for introducing air and an air outlet for providing the air to the FFU. The air inlet is larger than the air outlet.

### CROSS-REFERENCE TO RELATED APPLICATION(S)

This application claims the benefit of U.S. Provisional Application 63/467,533 filed on May 18, 2023, the entire contents of which are incorporated herein by reference.

### FIELD OF INVENTION

The present disclosure generally relates to an equipment front end module. More particularly, examples of the disclosure relate to an air intake port of an equipment front end module.

### BACKGROUND OF THE DISCLOSURE

In the field of semiconductor, a front opening unified pod (FOUP) is provided to hold a substrate. A substrate transfer robot transfers the substrate in the FOUP to an equipment front end module (EFEM). It is desirable to prevent the substrate from being contaminated. Generally, a clean air may be introduced from an air intake port to an interior of the EFEM in order to keep the substrate in an acceptable environment.

Due to a geometry of the air intake port, a situation may arise where the clean gas does not diffuse into the EFEM. Therefore, there is a need for a system that can effectively and efficiently diffuse a clean gas into an EFEM.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### SUMMARY OF THE DISCLOSURE

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

In accordance with exemplary embodiments of the disclosure, a substrate processing apparatus is provided. The apparatus may comprise: an equipment front end module (EFEM) comprising a housing bounded by a front wall, a back wall, first and second side walls between the front wall and the back wall, a top wall, and a bottom wall; a load port connected to the front wall and configured to receive a front opening unified pod (FOUP); a load lock chamber connected to the back wall and configured to load or unload a substrate; a front-end robot disposed in the housing and configured to transfer the substrate between the FOUP and the load lock; a fan filter unit (FFU) connected to the top wall and configured to provide filtered air to the housing; and an air intake port provided above the FFU, the air intake port comprising an air inlet for introducing an air and an air outlet for providing the air to the FFU; wherein the size of the air inlet is larger than that of the air outlet.

In various embodiments, the surface area of the air inlet may be between 0.24 m² and 0.56 m².

In various embodiments, the surface area of the air outlet may be between 0.1 m² and 0.32 m².

In various embodiments, the substrate processing apparatus may further comprise a fin disposed in the air intake port.

In various embodiments, the air intake port may further comprise a top portion including the air inlet for introducing the air and a bottom portion including the air outlet for providing the air to the FFU.

In various embodiments, the top portion may have a rectangular cuboid shape.

In various embodiments, the bottom portion may have a quadrilateral frustum (apex-truncated square pyramid) shape.

In various embodiments, a first surface area of the bottom portion may be bigger than a second surface area of the bottom portion.

In various embodiments, a surface area of the top portion may be bigger than the first surface area of the bottom portion.

In various embodiments, the substrate processing apparatus may further comprise an electric box disposed along the air intake port.

In various embodiments, the electric box may be disposed along the bottom portion.

In various embodiments, the substrate processing apparatus may further comprise: a reaction chamber for processing the substrate; a substrate handling chamber attached to the reaction chamber; the substrate handling chamber being attached to the load lock chamber.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 is a schematic plan view of a semiconductor processing apparatus with dual chamber modules usable in an embodiment of the present invention.

FIG. 2 is a schematic perspective view of a EFEM in accordance with exemplary embodiments of the disclosure.

FIG. 3a illustrates an airflow simulation image of an air intake port according to the prior art.

FIG. 3b illustrates an airflow simulation image of an air intake port in accordance with exemplary embodiments of the disclosure.

FIG. 3c illustrates an airflow simulation image of an air intake port in accordance with exemplary embodiments of the disclosure.

It will be appreciated that elements in the figures are illustrated for simplicity and clarity and have not necessarily been drawn to scale. For example, the dimensions of some of the elements in the figures may be exaggerated relative to other elements to help understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

As used herein, the term “film” and “thin film” may refer to any continuous or non-continuous structures and material deposited by the methods disclosed herein. For example, “film” and “thin film” could include 2D materials, nanorods, nanotubes, or nanoparticles or even partial or full molecular layers or partial or full atomic layers or clusters of atoms and/or molecules. “Film” and “thin film” may comprise material or a layer with pinholes, but still be at least partially continuous.

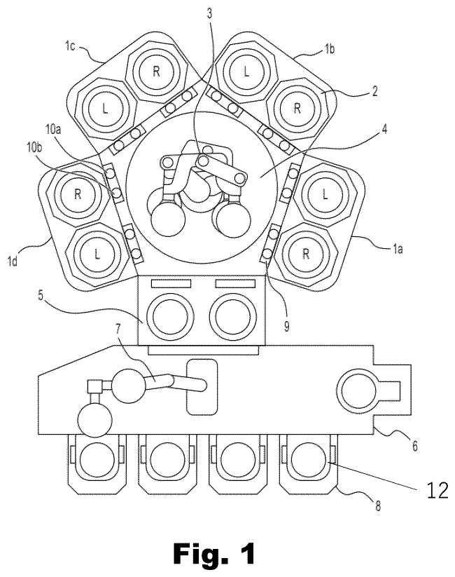

FIG. 1 is a schematic plan view of a substrate processing apparatus with dual chamber modules in some embodiments of the present invention. The substrate processing apparatus may comprise four dual chamber modules 1a, 1b, 1c, 1d (each provided with two reaction chambers 2), a load lock chamber 5, and a substrate handling chamber 4 provided with back-end robots 3, desirably in conjunction with controllers programmed to conduct the sequences described below, which can be used in some embodiments of the present invention.

In this embodiment, the substrate processing apparatus may comprise: (i) four dual chamber modules 1a-1d, each having two reaction chambers 2 arranged side by side (left (L) and right (R)) with their fronts aligned in a line; (ii) a substrate handling chamber 4 including two back end robots 3 (substrate handling robots), each having at least two end-effectors accessible to the two reaction chambers of each unit simultaneously, said substrate handling chamber 4 having a polygonal shape having four sides corresponding to and being attached to the four chamber modules 1a-1d, respectively, and one additional side for a load lock chamber 5, all the sides being disposed on the same plane; and (iii) a load lock 5 for loading or unloading two substrates simultaneously, the load lock chamber 5 being attached to the one additional side of the substrate handling chamber 4, wherein each back-end robot 3 is accessible to the load lock chamber 5.

The interior of each chamber 2 and the interior of the load lock chamber 5 may be isolated from the interior of the substrate handling chamber 4 by a gate valve 9. Further, auto wafer centering (AWC) sensors 10a, 10b may be disposed near the gate valve 9 between each chamber 2 and the substrate handling chamber 4 to determine, for example, at least an eccentricity of the substrate relative to a predetermined location of the back-end robot 3.

In some embodiments, a controller (not shown) may store software programmed to execute sequences of substrate transfer, for example. The controller may also: (1) check the status of each reaction chamber; (2) may position substrates in each reaction chamber using sensing systems including the AWC sensors 10a, 10b; (3) may control a gas box and an electric box for each module; (4) may control a front end robot 7 in an equipment front end module 6 based on a distribution status of substrates stored in a FOUP 12 of a load port 8 and the load lock chamber 5; (5) may control the back end robots 3; and/or (6) may control the gate valves 9.

A skilled artisan may appreciate that the apparatus includes one or more controller(s) programmed or otherwise configured to cause the deposition and reactor cleaning processes described elsewhere herein to be conducted. The controller(s) may communicate with the various power sources, heating systems, pumps, robotics and gas flow controllers or valves of the reactor, as will be appreciated by the skilled artisan.

In some embodiments, the apparatus may have any number of chamber modules and reaction chambers greater than one (e.g., 2, 3, 4, 5, 6, or 7). In FIG. 1, the apparatus has eight reaction chambers, but it may have ten or more. In some embodiments, the reaction chamber of the modules may be any suitable reactors for processing or treating wafers, including CVD reactors such as plasma-enhanced CVD reactors and thermal CVD reactors, ALD reactors such as plasma-enhanced ALD reactors and thermal ALD reactors, etching reactors, and UV-curing reactors. Typically, the reaction chambers are plasma reactors for depositing a thin film or layer on a wafer. In some embodiments, all the modules may be of the same type having identical capability for treating wafers so that the unloading/loading can sequentially and regularly be timed, thereby increasing productivity or throughput. In some embodiments, the modules may have different capacities (e.g., different treatments), but their handling times are substantially identical.

A skilled artisan will appreciate that the apparatus includes one or more controller(s) programmed or otherwise configured to cause one or more method steps as described herein to be conducted. The controller(s) are communicated with the various power sources, heating systems, pumps, robotics and gas flow controllers, or valves of the reactor, as will be appreciated by the skilled artisan.

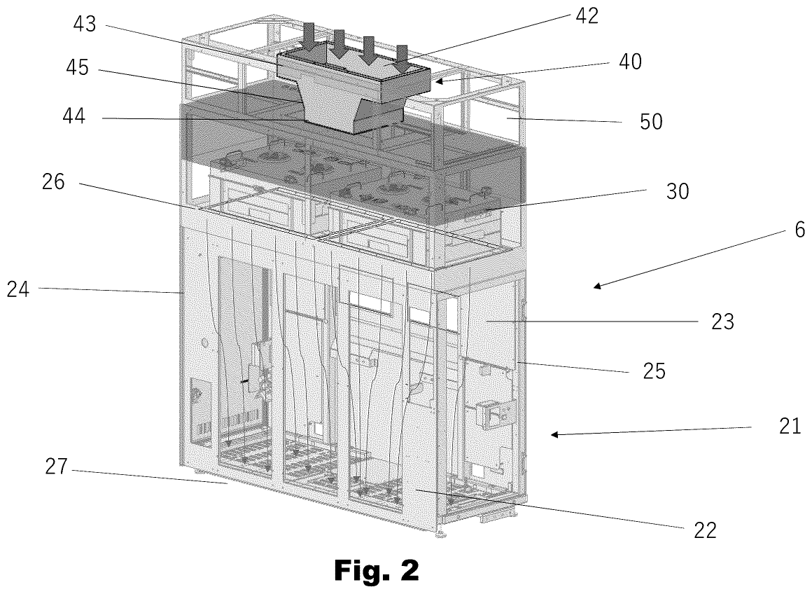

FIG. 2 is a schematic perspective view of a EFEM in accordance with exemplary embodiments of the disclosure. A substrate processing apparatus includes an EFEM 6 comprising a housing 21 bounded by a front wall 22, a back wall 23, first 24 and second 25 side walls between the front wall 22 and the back wall 23, a top wall 26, and a bottom wall 27. The substrate processing apparatus further includes: a load port 8 connected to the front wall 22 and configured to receive a FOUP 12; a load lock chamber 5 connected to the back wall 23 and configured to load or unload a substrate; a front-end robot 7 disposed in the housing 21 and configured to transfer the substrate between the FOUP 12 and the load lock 5; a fan filter unit (FFU) 30 connected to the top wall 26 and configured to provide filtered air to the housing 21; and an air intake port 40 provided above the FFU 30, the air intake port 40 comprising an air inlet 42 for introducing an air and an air outlet 44 for providing the air to the FFU 30. The size of the air inlet 42 is larger than that of the air outlet 44.

The surface area of the air inlet 42 may be between 0.24 m² and 0.56 m². The surface area of the air outlet 44 may be between 0.1 m² and 0.32 m².

The air intake port 40 may further comprise a top portion 43 including the air inlet 42 for introducing the air and a bottom portion 45 including the air outlet 44 for providing the air to the FFU 30.

The top portion 43 may have a rectangular cuboid shape. The bottom portion 45 may have a quadrilateral frustum (apex-truncated square pyramid) shape.

A first (top) surface area of the bottom portion 45 may be bigger than a second (bottom) surface area of the bottom portion. A surface area of the top portion 43 may be bigger than the first surface area of the bottom portion 45.

The substrate processing apparatus may further comprise an electric box 50 disposed along the air intake port 40. A space below the top portion 43 can be used when the electric box 50 is disposed along the bottom portion 45.

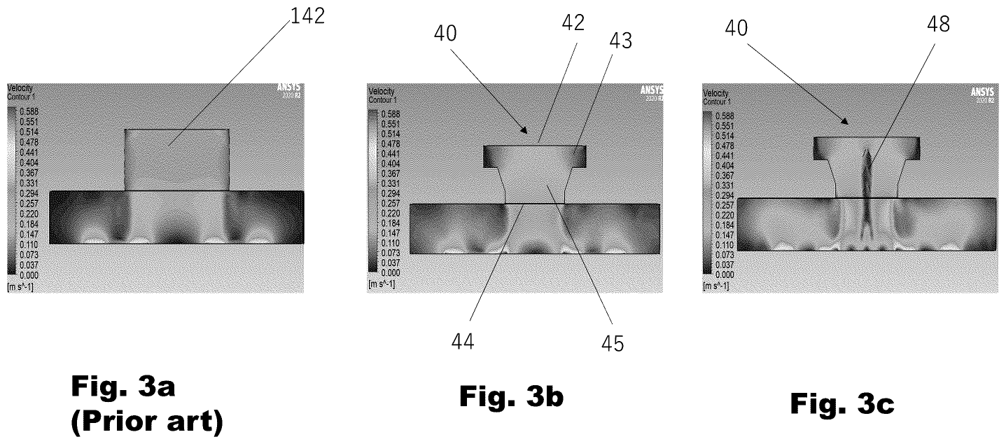

FIG. 3a illustrates an airflow simulation image of an air intake port according to the prior art. As shown in this simulation image, the clean gas may not be diffused enough if an air intake port 142 has a rectangular shape. If the clean gas is not sufficiently diffused, the clean gas may not reach all parts of the EFEM, leading to particular localized areas not receiving the clean gas, leading to more particles. FIG. 3b illustrates an airflow simulation image of an air intake port in accordance with exemplary embodiments of the disclosure. As shown in this simulation image, the clean gas may be diffused more sufficiently and efficiently since the size of the air inlet 42 is larger than that of the air outlet 44, resulting in the gas diffusion.

FIG. 3c illustrates an airflow simulation image of an air intake port in accordance with exemplary embodiments of the disclosure. A fin 48 may be disposed in the air intake port 40. As shown in this simulation image, the clean gas may be more spread throughout since the fin 48 may direct the gas flow to make gas diffuse more sufficiently.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

What is claimed is:

1. A substrate processing apparatus comprising:
an equipment front end module (EFEM) comprising a housing bounded by a front wall, a back wall, first and second side walls between the front wall and the back wall, a top wall, and a bottom wall;
a load port connected to the front wall and configured to receive a front opening unified pod (FOUP);
a load lock chamber connected to the back wall and configured to load or unload a substrate;
a front-end robot disposed in the housing and configured to transfer the substrate between the FOUP and the load lock chamber;
a fan filter unit (FFU) connected to the top wall and configured to provide filtered air to the housing; and
an air intake port provided above the FFU, the air intake port comprising an air inlet for introducing air, and an air outlet for providing the air to the FFU,
wherein the size of the air inlet is larger than that of the air outlet.

2. The apparatus of claim 1, wherein the surface area of the air inlet is between 0.24 m² and 0.56 m².

3. The apparatus of claim 1, wherein the surface area of the air outlet is between 0.1 m² and 0.32 m².

4. The apparatus of claim 1, further comprising a fin disposed in the air intake port.

5. The apparatus of claim 1, the air intake port further comprising a top portion including the air inlet for introducing the air and a bottom portion including the air outlet for providing the air to the FFU.

6. The apparatus of claim 5, wherein the top portion has a rectangular cuboid shape.

7. The apparatus of claim 5, wherein the bottom portion has a quadrilateral frustum (apex-truncated square pyramid) shape.

8. The apparatus of claim 7, wherein a first surface area of the bottom portion is bigger than a second surface area of the bottom portion.

9. The apparatus of claim 8, wherein a surface area of the top portion is bigger than the first surface area of the bottom portion.

10. The apparatus of claim 1, further comprising an electric box disposed along the air intake port.

11. The apparatus of claim 10, wherein the electric box is disposed along the bottom portion.

12. The apparatus of claim 1, further comprising:
a reaction chamber for processing the substrate; and
a substrate handling chamber attached to the reaction chamber, the substrate handling chamber being attached to the load lock chamber.
